(19) United States
(12) Patent Application Publication
(10) Pub. No.: US 2026/0190519 A1
(43) Pub. Date: Jul. 2, 2026

(54) IMAGE SENSOR PIXEL CELL WITH SPLIT FLOATING DIFFUSION

(71) Applicant: OMNIVISION TECHNOLOGIES, INC., Santa Clara, CA (US)

(72) Inventor: Sang Joo Lee, Sunnyvale, CA (US)

(21) Appl. No.: 19/003,328

(22) Filed: Dec. 27, 2024

(51) Int. Cl. H10F 39/00

(52) U.S. Cl. CPC H10F 39/8027; H10F 39/807

(57) ABSTRACT

A pixel cell for an image sensor is described. The pixel cell includes a plurality of photodiodes including a first photodiode and a second photodiode, a split floating diffusion including a first floating diffusion region and a second floating diffusion region, a plurality of transfer gate electrodes including a first transfer gate electrode and a second transfer gate electrode, and a gate electrode of a transistor disposed between the first floating diffusion and the second floating diffusion region. The first transfer gate electrode is disposed between the first photodiode and the first floating diffusion region. The second transfer gate electrode is disposed between the second photodiode and the second floating diffusion region. The first floating diffusion region and the second floating diffusion region form respective junction regions of the transistor.

### TECHNICAL FIELD

This disclosure relates generally to image sensors, and in particular but not exclusively, relates to CMOS image sensors and applications thereof.

### BACKGROUND INFORMATION

Image sensors are one type of semiconductor device that have become ubiquitous and are now widely used in digital cameras, cellular phones, security cameras, as well as, medical, automobile, and other applications. As image sensors are integrated into a broader range of electronic devices it is desirable to enhance their functionality, performance metrics, and the like in as many ways as possible (e.g., resolution, power consumption, dynamic range, size, etc.) through both device architecture design as well as image acquisition processing. However, it is appreciated that many of these metrics are inversely related. For example, pixel size may be increased to improve dynamic range but have increased noise. In another example, resolution may be increased by increasing the number of pixels, but if pixel size is maintained then the physical size of the image sensor increases. Accordingly, improving one or more performance metrics of semiconductor devices such as image sensors while mitigating adverse effects on other performance metrics remains challenging.

The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which is readout as analog image signals from the column bitlines and converted to digital values to produce digital images (i.e., image data) representative of the external scene.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1A illustrates a block diagram of an imaging system, in accordance with an embodiment of the disclosure.

FIG. 1B illustrates a plan view of an example layout for the pixel cell with a split floating diffusion included in the imaging system of FIG. 1A, in accordance with an embodiment of the disclosure.

FIG. 1C illustrates a cross-sectional view of the pixel cell illustrated in FIG. 1B along line X-X′, in accordance with an embodiment of the disclosure

FIG. 1D illustrates a partial view of the pixel cell array illustrated in FIG. 1A including an example two-by-two arrangement of pixel cells each having a split floating diffusion, in accordance with an embodiment of the disclosure.

FIG. 2 illustrates a plan view of an example layout for a pixel cell with a split floating diffusion that is capable of dual conversion gain operation, in accordance with an embodiment of the disclosure.

FIG. 3 illustrates a plan view of an example layout for a pixel cell with a split floating diffusion that is capable of triple conversion gain operation, in accordance with an embodiment of the disclosure.

FIG. 4A illustrates a pixel cell corresponding to the pixel cell illustrated in FIG. 1B with a parallel source-follower gate electrode arrangement, in accordance with an embodiment of the disclosure.

FIG. 4B illustrates a pixel cell corresponding to the pixel cell illustrated in FIG. 2 with a parallel source-follower gate electrode arrangement, in accordance with an embodiment of the disclosure.

FIG. 4C illustrates a pixel cell corresponding to the pixel cell illustrated in FIG. 3 with a parallel source-follower gate electrode arrangement, in accordance with an embodiment of the disclosure.

### DETAILED DESCRIPTION

Embodiments of an apparatus, system, and method each related to a pixel cell of an imaging system or image sensor with a split floating diffusion are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

Embodiments of the disclosure describe image sensors or imaging systems with pixel cells having a split floating diffusion. In conventional imaging systems, floating diffusions may be coupled to circuitry components using metal wires that may increase the effective capacitance of the floating diffusion and thereby reduce conversion gain. To increase conversion gain, embodiments of the disclosure utilize pixel cell layouts with a split floating diffusion, which in conjunction with the arrangement of components described in embodiments of the disclosure, results in increased conversion gain, reduced or removed floating diffusion wiring, reduced number of metal layers within a metallization region, simplified routing, and reduced fixed pattern noise.

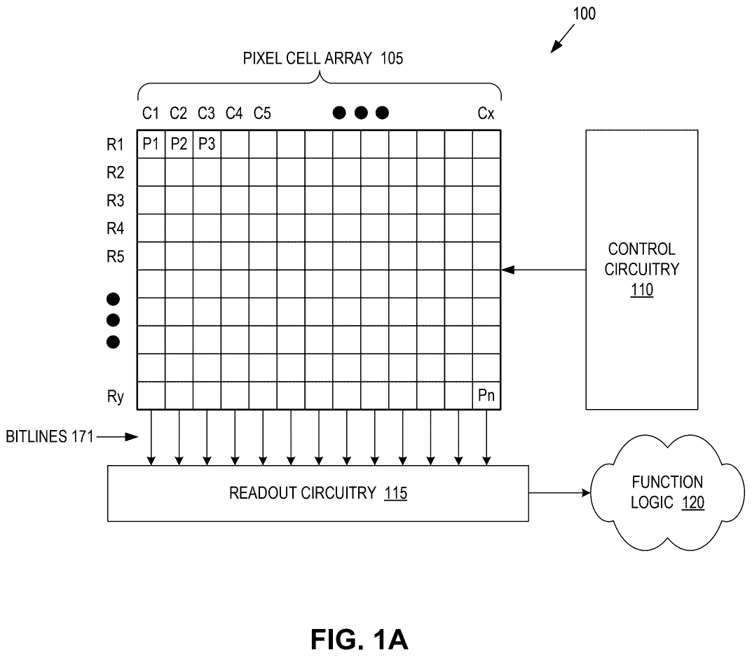

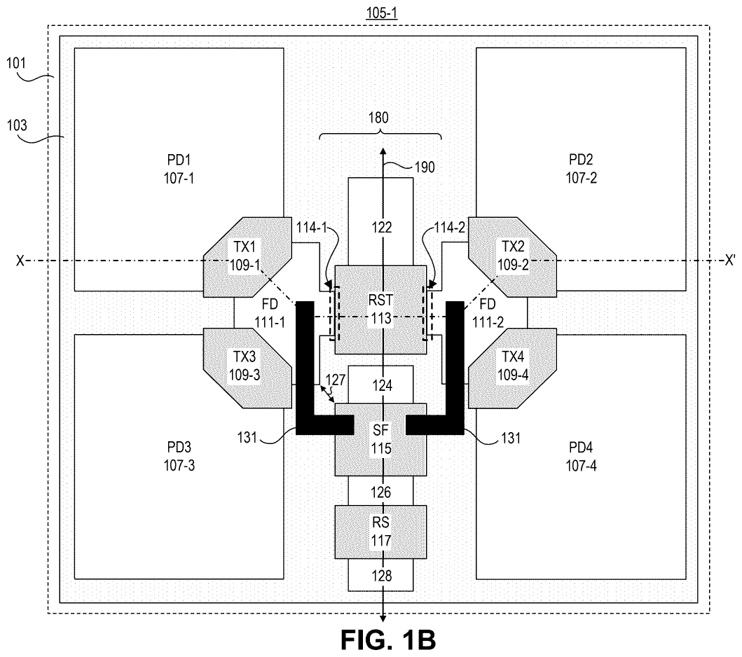

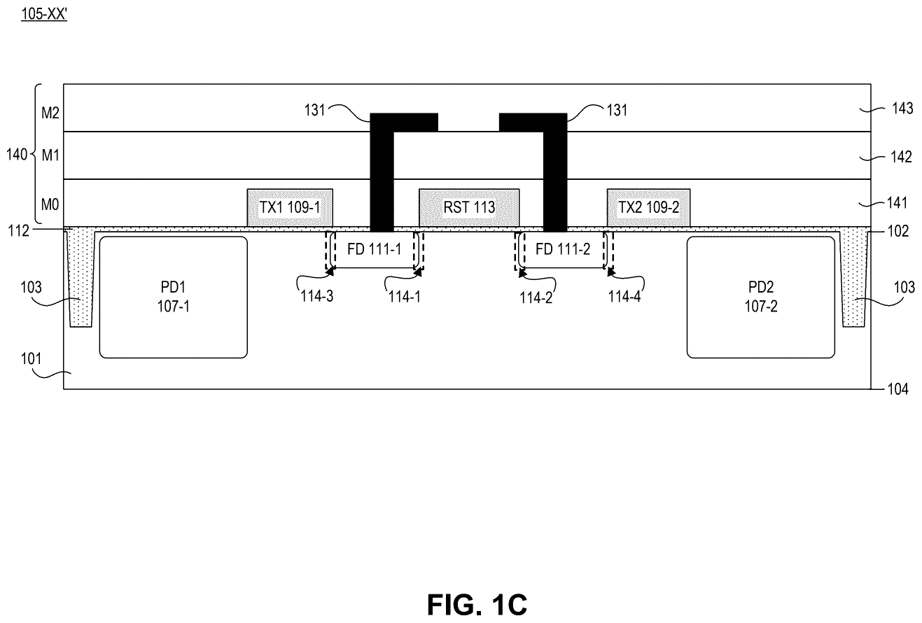

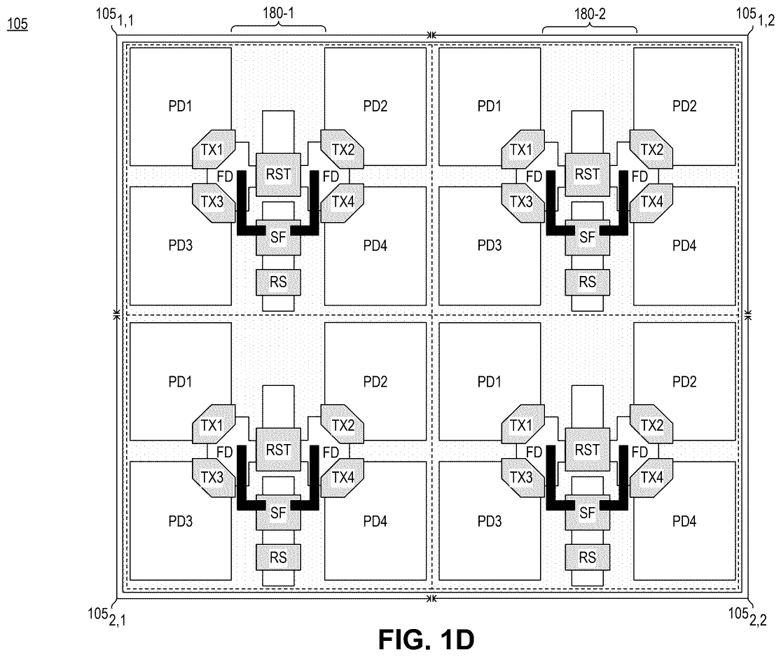

FIG. 1A illustrates a block diagram of an imaging system 100, in accordance with an embodiment of the disclosure. In particular, imaging system 100 includes a pixel cell array 105, control circuitry 110, readout circuitry 115, function logic 120, and a plurality of bitlines 171. In one embodiment, pixel cell array 105 is a two-dimensional array including a plurality of pixel cells (e.g., P1, P2, P3, . . . Pn) that are arranged in rows (e.g., R1 to Ry) and columns (e.g., C1 to Cx) to acquire image data of a person, place, object, etc., which can be used to render an image of the person, place, object, etc. In some embodiments, each of the plurality of pixel cells included pixel cell array 105 may include one, two, four or more photodiodes. In the same or different embodiments, each of the plurality of pixel cells included in pixel cell array 105 may include a split floating diffusion structure coupled to a subset of photodiodes. In the same or different embodiments, each of the plurality of pixel cells included in pixel cell array 105 may include one or more capacitors coupled to one or more photodiodes. In some embodiments, readout circuitry 115 may be configured to read out image data (e.g., representative of image charge photogenerated by photodiodes included in the plurality of pixel cells in the pixel cell array 105 in response to incident light) through plurality of bitlines 171 (e.g., column bitlines). In some embodiments, readout circuitry 115 may include amplification circuitry, analog-to-digital (ADC) circuitry, sample-and-hold circuitry, image buffers, or other circuitry components to facilitate converting an analog signal (e.g., image signals) to a digital signal (e.g., image data). Image data output by readout circuitry 115 may then be received by function logic 120. Function logic 120 is coupled to readout circuitry 115 to receive image data to de-mosaic the image data and generate one or more image frames. In some embodiments, the electrical signals and/or image data can be manipulated or otherwise processed by function logic 120 (e.g., apply post image effects such as crop, rotate, remove red eye, adjust brightness, adjust contrast, or otherwise).

FIG. 1B illustrates a plan view of an example layout for pixel cell 105-1 with a split floating diffusion 111 (i.e., first floating diffusion region 111-1 and second floating diffusion region 111-2) included in imaging system 100 of FIG. 1A, in accordance with an embodiment of the disclosure. Pixel cell 105-1 may be representative of each instance of a pixel cell (e.g., P1, P2, P3, . . . , Pn) included in pixel cell array 105. In other words, multiple instances of pixel cell 105-1 may be arranged in rows and columns to form pixel cell array 105 in accordance with embodiments of the disclosure. Pixel cell 105-1 includes a plurality of photodiodes 107 including a first photodiode (PD1) 107-1, a second photodiode (PD2) 107-2, a third photodiode (PD3) 107-3, and a fourth photodiode (PD4) 107-4, a plurality of transfer gate electrodes 109 including a first transfer gate electrode (TX1) 109-1 associated with a first transfer transistor, a second transfer gate electrode (TX2) 109-2 associated with a second transfer transistor, a third transfer gate electrode (TX3) 109-3 associated with a third transfer transistor, and a fourth transfer gate electrode (TX4) 109-4 associated with a fourth transfer transistor, a split floating diffusion (FD) 111 including first floating diffusion region 111-1 and second floating diffusion region 111-2, a reset gate electrode (RST) 113 associated with a reset transistor, a source-follower gate electrode (SF) 115 associated with a source-follower transistor, a row select gate electrode (RS) 117 associated with a row select transistor, a plurality of source/drain regions including source/drain regions 122, 124, 126, and 128 associated with the aforementioned reset transistor, source-follower transistor, and/or row select transistor, and one or more interconnects (e.g., one or more wires and vias represented by one or more wires 131); each of which is formed in or on semiconductor material 101. In some embodiments, pixel cell 105-1 further includes an isolation structure 103 formed in semiconductor material 101.

Plurality of photodiodes 107 are configured to photogenerate image charge in response to incident light. Individual photodiodes included in plurality of photodiodes 107 are coupled to respective ones of plurality of transfer gate electrodes 109 adapted to transfer image charge to a corresponding region of split floating diffusion 111 (e.g., first floating diffusion region 111-1 or second floating diffusion region 111-2). In the illustrated embodiment, split floating diffusion 111 includes two separate floating diffusion regions (i.e., first floating diffusion region 111-1 coupled to receive image charge from first photodiode 107-1 and third photodiode 107-3 and second floating diffusion region 111-2 coupled to receive image charge from second photodiode 107-2 and fourth photodiode 107-4) to collectively form a first floating diffusion of pixel cell 105-1. It is appreciated first floating diffusion region 111-1 and second floating diffusion region 111-2 of split floating diffusion 111 are coupled together directly or indirectly via one or more wires 131 formed in a metallization region (see, e.g., FIG. 1C) forming a first floating diffusion of pixel cell 105-1. Put in another way, the term “split floating diffusion” used in embodiments herein corresponds to a floating diffusion that includes two physically separated floating diffusion regions (e.g., doped or otherwise formed in semiconductor material 101) that are directly electrically connected to one another (e.g., both first floating diffusion region 111-1 and second floating diffusion 111-2 are utilized to store image charge from one or more coupled photodiodes included in pixel cell 105-1 for signal readout during a highest conversion gain operation of pixel cell 105-1 such as during a high conversion gain operation). In some embodiments, a direct electrical connection between first floating diffusion region 111-1 and second floating diffusion region 111-2 is achieved outside of semiconductor material 101. For example, respective metal wires included in one or more metal wires 131 electrically couple first floating diffusion region 111-1 to second floating diffusion region 111-2. In some embodiments, source-follower gate electrode 115 bridges an electrical connection between first floating diffusion region 111-1 and second floating diffusion region 111-2. In other embodiments, one or more metal wires 131 directly electrically couple first floating diffusion region 111-1 to second floating diffusion region 111-2 without source-follower gate electrode 115 acting as a bridge.

In the illustrated embodiment, pixel cell 105-1 employs a layout of components, in conjunction with split floating diffusion 111, that has the benefit of reduced effective floating diffusion capacitance and thus increased overall conversion gain for pixel cell 105-1. Increased conversion gain is achieved, at least in part, by reducing the capacitance contribution to split floating diffusion 111 from wires (e.g., interconnections formed within a metallization region such as metal wires). For example, instead of using metal wire interconnections to couple split floating diffusion 111 to a source/drain region of the reset transistor associated with reset gate electrode 113, first floating diffusion region 111-1 and second floating diffusion region 111-2 extend within semiconductor material 101 proximate to reset gate electrode 113 to form respective junction regions 114-1 and 114-2 of the reset transistor. In some embodiments, first floating diffusion region 111-1 extends continuously within semiconductor material 101 from proximate to reset gate electrode 113 to proximate both first transfer gate electrode 109-1 and third transfer gate electrode 109-3 when viewed from the illustrated plan view. Similarly, second floating diffusion region 111-2 extends continuously within semiconductor material 101 from proximate to reset gate electrode 113 to proximate both second transfer gate electrode 109-2 and fourth transfer gate electrode 109-4 when viewed from the illustrated plan view. In such a way the reset transistor associated with reset gate electrode 113 is coupled to first floating diffusion region 111-1 and second floating diffusion region 111-2 without any metal wire connection or other interconnect formed within a metallization region (e.g., metallization region 140 illustrated in FIG. 1C). Therefore, in some embodiments, first floating diffusion region 111-1 corresponds to source/drain regions for the reset transistor associated with reset gate electrode 113 and the transfer transistors associated with first transfer gate electrode 109-1 and third transfer gate electrode 109-3. Similarly, in some embodiments, second floating diffusion region 111-2 corresponds to source/drain regions for the reset transistor associated with reset gate electrode 113 and the transfer transistors associated with second transfer gate electrode 109-2 and fourth transfer gate electrode 109-4.

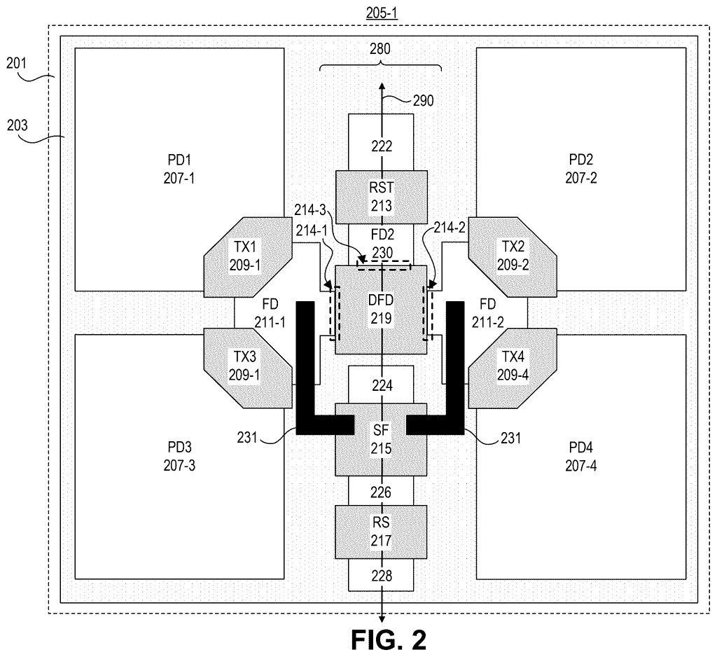

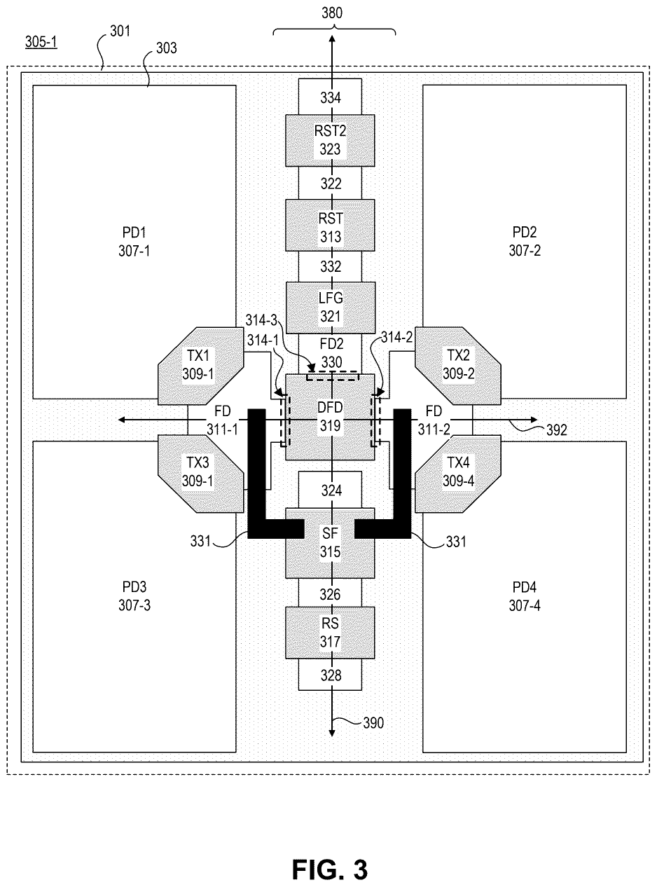

Additionally, by defining a transistor area 180 (e.g., via isolation structure 103) disposed between pairs of photodiodes (e.g., a first pair of photodiodes including first photodiode 107-1 and third photodiode 107-3 and a second pair of photodiodes including second photodiode 107-2 and fourth photodiode 107-4) of pixel cell 105-1, the lateral area of split floating diffusion 111 may be reduced and furthermore the distance metal wires need to traverse to couple split floating diffusion 111 to other components (e.g., source-follower gate electrode 115) may also be reduced, which advantageously decreases effective capacitance associated with split floating diffusion 111 and thereby further increases conversion gain for pixel cell 105-1. Accordingly, embodiments of the disclosure may significantly reduce wiring coupled to split floating diffusion 111 (e.g., from twice a pixel cell pitch to approximately equal to pixel cell pitch). Other advantages of the example layout for pixel cell 105-1 illustrated in FIG. 1B include a symmetric floating diffusion design (e.g., first floating diffusion region 111-1 is mirror symmetric with second floating diffusion region 111-2 about direction 190) for reduced fixed pattern noise, signal non-uniformity, simplified routing (e.g., within metallization region 140 illustrated in FIG. 1C) between components due to shortened routing, reducing layers of routing (e.g., one or more wires 131 may be formed within layer M0 of metallization region 140 illustrated in FIG. 1C), and compatibility with multi-conversion gain mode configurations (see, e.g., FIG. 2 and FIG. 3).

In the illustrated embodiment of FIG. 1B, first photodiode 107-1 and second photodiode 107-2 are horizontally aligned and arranged in a first row (e.g., row n) and adjacent columns (e.g., column m and m+1, respectively). In the same embodiment, third photodiode 107-3 and fourth photodiode 107-4 are horizontally aligned and arranged in a second row (e.g., row n+1) adjacent to the first row and adjacent columns (e.g., column m and m+1, respectively). In the same embodiments, first photodiode 107-1 and photodiode 107-3 are vertically aligned in a first column (e.g., column m). In the same embodiment, second photodiode 107-2 and fourth photodiode 107-4 are vertically aligned in a second column (e.g., column m+1). In such an arrangement, first transfer gate electrode 109-1 is disposed between first photodiode 107-1 and first floating diffusion region 111-1, second transfer gate electrode 109-2 is disposed between second photodiode 107-2 and second floating diffusion region 111-2, third transfer gate electrode 109-3 is disposed between third photodiode 107-3 and first floating diffusion region 111-1, and fourth transfer gate electrode 109-4 is disposed between fourth photodiode 107-4 and second floating diffusion region 111-2. In the same or other embodiments, reset gate electrode 113 is disposed between first floating diffusion region 111-1 and second floating diffusion region 111-2. It is further appreciated that components disposed between the first pair of photodiodes (i.e., first photodiode 107-1 and third photodiode 107-3) and the second pair of photodiodes (i.e., second photodiode 107-2 and fourth photodiode 107-4) when viewed from the illustrated plan view of FIG. 1B includes components formed in or on transistor area 180 (e.g., source/drain regions 122, 124, 126, and 128, reset gate electrode 113, source-follower gate electrode 115, and row select gate electrode 117). In the same or other embodiments, source-follower gate electrode 115, row select gate electrode 117, and source/drain regions 124, 126, and 128 are disposed between a first set of adjacent photodiodes (e.g., third photodiode 107-3 and fourth photodiode 107-4) while source/drain region 122 is disposed between a second set of adjacent photodiodes (e.g., first photodiode 107-1 and second photodiode 107-2) different from the first set of adjacent photodiodes.

In some embodiments, reset gate electrode 113 is laterally surrounded by plurality of transfer gate electrodes 109 (e.g., first transfer gate electrode 109-1, second transfer gate electrode 109-2, third transfer gate electrode 109-3, and fourth transfer gate electrode 109-4). In the same or other embodiments, reset gate electrode 113 is laterally surrounded by plurality of photodiodes 107 (e.g., first photodiode 107-1, second photodiode 107-2, third photodiode 107-3, and fourth photodiode 107-4). In some embodiments, reset gate electrode 113 is centrally located between plurality of transfer gate electrodes 109 and/or plurality of photodiodes 107 when viewed from the illustrated plan view of FIG. 1B. In the illustrated embodiment, first floating diffusion region 111-1 and second floating diffusion region 111-2 are coupled to opposite sides of reset gate electrode 113 (e.g., junction regions 114-1 and 114-2 are formed proximate to opposite sides of reset gate electrode 113). In the same or other embodiments, a first lateral distance between each of first floating diffusion region 111-1 and second floating diffusion region 111-2 to reset gate electrode 113 (e.g., corresponding to a lateral distance extending perpendicular to direction 190 between junction regions 114-1, 114-2 and reset gate electrode 113 which is not amenable to illustration due to the close proximity between the aforementioned elements) is less than a second lateral distance from each of first floating diffusion region 111-1 and second floating diffusion region 111-2 to source-follower gate electrode 115 of the source-follower transistor (e.g., lateral distance 127 from first floating diffusion 111-1 and source-follower gate electrode 115). It is appreciated that the term “lateral distance” indicates any distance along a direction parallel to a surface of semiconductor material 101 (e.g., first side 102 and/or second side 104 illustrated in FIG. 1C). For example, the illustrated plane of FIG. 1B may correspond to an x-y plane parallel to a surface of semiconductor material 101 and a lateral distance may extend along a direction (e.g., having x and/or y components) that is parallel to the x-y plane. In such an embodiment, the first lateral distance corresponds to a shortest distance from first floating diffusion region 111-1 and/or second floating diffusion region 111-2 to reset gate electrode 113 along a direction parallel to the x-y plane while the second lateral distance corresponds to a shortest distance from first floating diffusion region 111-1 and/or second floating diffusion region 111-2 to source-follower gate electrode 115 parallel to the x-y plane. Put in another way, lateral distances are described in context of a plan view or planar projection of pixel cell 105. In the same or other embodiments, a first pair of transfer gate electrodes (e.g., first transfer gate electrode 109-1 and third transfer gate electrode 109-3) are disposed between the first pair of photodiodes (e.g., first photodiode 107-1 and third photodiode 107-3) and first floating diffusion region 111-1. Similarly, a second pair of transfer gate electrodes (e.g., second transfer gate electrode 109-2 and fourth transfer gate electrode 109-4) are disposed between the second pair of photodiodes (e.g., second photodiode 107-2 and fourth photodiode 107-4) and second floating diffusion region 111-2.

In the same or other embodiments, components included in transistor area 180 are aligned along a same direction 190. For example, reset gate electrode 113, source-follower gate electrode 115, row select gate electrode 117, and source/drain regions 122, 124, 126, and 128 are aligned along direction 190 extending between first photodiode 107-1 and second photodiode 107-2 and further extending between third photodiode 107-3 and fourth photodiode 107-4. Thus in some embodiments, direction 190 overlaps with each of reset gate electrode 113, source-follower gate electrode 115, row select gate electrode 117, and source/drain regions 122, 124, 126, and 128. In the same or other embodiments, direction 190 overlaps with a midpoint or center of each of reset gate electrode 113, source-follower gate electrode 115, row select gate electrode 117, and source/drain regions 122, 124, 126, and 128. In the same or other embodiments, one or more edges of reset gate electrode 113, source-follower gate electrode 115, and row select gate electrode 117 are aligned. For example, source-follower gate electrode 115 may be aligned with reset gate electrode 113 such that edges of source-follower gate electrode 115 may be aligned with respective edges of reset gate electrode 113 (e.g., left edges aligned with left edges and right edges aligned with right edges).

In some embodiments, pixel cell 105-1 is operated (e.g., in terms of reset, integration, and readout) in a manner similar to a 4T active pixel architecture. For example, source-drain regions 122 and 124 may correspond to or otherwise be coupled to respective voltage sources (e.g., to receive an analog voltage such as AVDD), source/drain region 126 corresponds to a shared source/drain region associated with source-follower gate electrode 115 and row select gate electrode 117, and source/drain region 128 corresponds to or is otherwise coupled to a bitline included in a plurality of bitlines (e.g., plurality of bitlines 171 illustrated in FIG. 1A). In such an embodiment, plurality of transfer gate electrodes 109 selectively couple plurality of photodiodes 107 to split floating diffusion region 111 based on corresponding transfer signals applied to plurality of transfer gate electrodes 109 (e.g., a transfer signal applied to first transfer gate electrode 109-1 determines whether or not first photodiode 107-1 is electrically coupled first floating diffusion region 111-1, a transfer signal applied to second transfer gate electrode 109-2 determines whether or not second photodiode 107-2 is electrically coupled to second floating diffusion region 111-2, and so on). In the same or other embodiments, a reset transistor including a reset gate electrode 113 is configured to selectively reset split floating diffusion 111 including first floating diffusion region 111-1 and second floating diffusion region 111-2, and plurality of photodiodes 107 including first photodiode 107-1, second photodiode 107-2, third photodiode 107-3, and/or fourth photodiode 107-4 to a reference voltage level (e.g., based on an analog supply voltage AVDD corresponding to or coupled to source/drain region 122) upon receiving a reset signal applied to reset gate electrode 113.

In the same or other embodiments, a source-follower transistor including a source-follower gate electrode 115 coupled to split floating diffusion 111 including both first floating diffusion region 111-1 and second floating diffusion region 111-2 and a row select transistor including row select gate electrode 117 are coupled and configured to selectively output an image signal to a bitline (e.g., through source/drain region 128). More specifically, during operation image charge photogenerated within or proximate to first photodiode 107-1, second photodiode 107-2, third photodiode 107-3, and/or fourth photodiode 107-4 may be selectively transferred to split floating diffusion 111, which is applied to source-follower gate electrode 115 to turn “on” the source-follower transistor and generate an image signal that may be readout to the bitline when the row select transistor is turned on based on the row select signal applied to row select gate electrode 117. It is appreciated that the image signal is proportional to the amount of image charge transferred from first photodiode 107-1, second photodiode 107-2, third photodiode 107-3, and/or fourth photodiode 107-4 to split floating diffusion 111 and is thus representative of an intensity of light of a given color (e.g., based on an overlying color filter) incident on first photodiode 107-1, second photodiode 107-2, third photodiode 107-3, and/or fourth photodiode 107-4.

It is appreciated that FIG. 1B illustrates pixel cell 105-1 including a plurality of transfer transistors, a reset transistor, a source-follower transistor, and a reset transistor for single conversion gain mode of operation, other implementations of pixel cell 105-1 may be utilized to enable multiple gain modes of operation for each pixel cell (see, e.g., FIG. 2 showing a pixel cell layout capable of dual conversion gain operation and FIG. 3 showing a pixel cell layout capable of triple conversion gain operation).

In some embodiments, floating diffusions (e.g., split floating diffusion 111 including first floating diffusion region 111-1 and second floating diffusion region 111-2), source/drain regions (e.g., source/drain regions 122, 124, 126, and 128), and photodiodes (e.g., first photodiode 107-1, second photodiode 107-2, third photodiode 107-3, and fourth photodiode 107-4) of pixel cell 105-1 correspond to doped regions disposed or formed within semiconductor material 101. In some embodiments, semiconductor material 101 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, semiconductor material 101 may correspond to any semiconductor material or combination of materials that may be doped or otherwise configured to facilitate the formation of an integrated circuit (e.g., individual circuitry components such as source/drain regions of transistors, memory elements, photodiodes, or the like). In one embodiment, semiconductor material 101 corresponds to an epitaxial layer (e.g., P-type silicon layer or N-type silicon layer). In such an embodiment, photodiodes (e.g., first photodiode 107-1, second photodiode 107-2, third photodiode 107-3, and fourth photodiode 107-4) may be formed in the epitaxial layer corresponding to semiconductor material 101.

It is appreciated that the term “photodiode” corresponds to a doped region (e.g., formed via implantation) disposed within or otherwise surrounded by an oppositely doped region to form a photosensitive area capable of photogenerating image charge in response to incident light. For example, first photodiode 107-1 and/or second photodiode 107-2 may correspond to an N-type semiconductor region (e.g., N-doped silicon region) disposed within a P-type semiconductor material (e.g., P-type doped silicon corresponding to semiconductor material 101). Accordingly, in some embodiments first photodiode 107-1, second photodiode 107-2, third photodiode 107-3, and fourth photodiode 107-4 or other photodiodes included in embodiments of the disclosure each includes a doped region that is oppositely doped (e.g., opposite conductivity type) relative to a doping type of semiconductor material 101. Other components formed within semiconductor material 101 such as split floating diffusion 111 including first floating diffusion region 111-1 and second floating diffusion region 111-2, source/drain regions such as source/drain regions 122, 124, 126, and 128, and the like also corresponds to doped regions (e.g., via implantation) disposed or otherwise formed within semiconductor material 101 that have an opposite conductivity type relative to semiconductor material 101 or other surrounding medium.

In some embodiments, gate electrodes included in pixel cell 105-1 (e.g., first transfer gate electrode 109-1, second transfer gate electrode 109-2, third transfer gate electrode 109-3, fourth transfer gate electrode 109-4, reset gate electrode 113, source-follower gate electrode 115, and reset gate electrode 117) are disposed within an interlayer dielectric region (see, e.g., within a layer of metallization region 140 of FIG. 1C corresponding to M0 included in metallization region 140 of FIG. 1C) proximate to a gate dielectric (see, e.g., gate dielectric 112 illustrated in FIG. 1C). In some embodiments, gate electrodes included in pixel cell 105-1 and formed within the interlayer dielectric region may include or otherwise correspond to a metal material (e.g., Au, Ag, Al, Cu, Ta, Ti, Nb, W, Mo), polycrystalline silicon (extrinsic or intrinsic), a silicide material, metal composites (e.g., WN, TiN, TaN, TiAl, TiAlC, other metal nitrides, RuOₓ, or other metal oxide electrode materials), other conductive materials with the appropriate conductivity and work function, or combinations thereof to facilitate image charge transfer. In some embodiments, gate electrodes formed within the interlayer dielectric region may be encapsulated by an interlayer dielectric material, which may include one or more insulating materials (e.g., silicon dioxide, a tetraethylorthosilicate, a high density plasma oxide material, other insulating materials, or combinations thereof).

In the same or other embodiments, one or more wires 131 is formed within a metallization region (e.g., any one of or a combination of M0, M1, M2, and/or other layers included in metallization region 140 illustrated in FIG. 1C) and may include or otherwise correspond to a metal material (e.g., Au, Ag, Al, Cu, Ta, Ti, Nb, W, Mo), polycrystalline silicon (extrinsic or intrinsic), a silicide material, metal composites (e.g., WN, TiN, TaN, TiAl, TiAlC, other metal nitrides, RuOₓ, or other metal oxide electrode materials), other conductive materials with the appropriate conductivity and work function, or combinations thereof to facilitate image charge transfer. It is appreciated that in some embodiments, one or more wires 131 includes both lateral wires (e.g., metal interconnect) and vertical wires (e.g., vias) to enable split floating diffusion 111 to be electrically coupled to source-follower gate electrode 115.

FIG. 1C illustrates a cross-sectional view of pixel cell 105-1 illustrated in FIG. 1B along line X-X′, in accordance with an embodiment of the disclosure. In the illustrated embodiment, semiconductor material 101 includes a first side 102 (e.g., a front side or non-illuminated side) and a second side 104 (e.g., a backside or illuminated side). Disposed within semiconductor material 101 between first side 102 and second side 104 includes first photodiode 107-1, second photodiode 107-2, split floating diffusion 111 including first floating diffusion region 111-1 and second floating diffusion region 111-2, and isolation structure 103. Isolation structure 103 may define photodiode regions (e.g., areas within semiconductor material 101 for forming plurality of photodiodes 107) and transistor areas (e.g., transistor area 180 illustrated in FIG. 1B) and may include a trench isolation structure (e.g., a shallow trench isolation structure as illustrated and/or a deep trench isolation structure including one or more insulating materials such as silicon dioxide) and/or an implant isolation structure (e.g., implanted well isolation structures doped to have a doping or conductivity type opposite of the doping or conductivity type of plurality of photodiodes 107 and split floating diffusion 111) to physically and electrically isolate intra-and inter-pixel cell components.

As illustrated, first floating diffusion region 111-1 is adjacent to both first transfer gate electrode 109-1 and reset gate electrode 113 while second floating diffusion region 111-2 is adjacent to both second transfer gate electrode 109-2 and reset gate electrode 113. In one embodiment, first floating diffusion region 111-1 extends within semiconductor material 101 from proximate to first transfer gate electrode 109-1 to proximate reset gate electrode 113 to form respective junction regions 114-1 and 114-3 within semiconductor material 101 such that first floating diffusion region 111-1 corresponds to source/drain regions associated with the transfer transistor that includes first transfer gate electrode 109-1 and the reset transistor that includes reset gate electrode 113. In the same or another embodiment, second floating diffusion region 111-2 extends within semiconductor material 101 from proximate to second transfer gate electrode 109-2 to proximate reset gate electrode 113 to form respective junction regions 114-2 and 114-4 within semiconductor material 101 such that second floating diffusion region 111-2 corresponds to source/drain regions associated with the transfer transistor that includes second transfer gate electrode 109-2 and the reset transistor that includes reset gate electrode 113. It is appreciated that junction regions 114-1, 114-2, 114-3, and 114-4 and other junction regions throughout the disclosure correspond to regions where there is an interface of boundary between semiconductor material types (e.g., a PN junction such as an interface where an N-type region corresponding to first floating diffusion region 111-1 and/or second floating diffusion region 111-2 meets a P-type region corresponding to semiconductor material 101). Put in another way, the term junction region corresponds to an interface where a source or drain region of a given transistor begins or terminates when the source or drain region for the given transistor is formed within semiconductor material 101.

Gate dielectric 112 is disposed proximate to first side 102 of semiconductor material and configured to correspond to the gate dielectric of the transfer transistor associated with first transfer gate electrode 109-1, the transfer transistor associated with second transfer gate electrode 109-2, and/or the reset transistor associated with reset gate electrode 113. In other words, in some embodiments gate dielectric 112 isolations or otherwise separates first transfer gate electrode 109-1, second transfer gate electrode 109-2, and/or reset gate electrode 113 from first photodiode 107-1, second photodiode 107-2, first floating diffusion region 111-1, and/or second floating diffusion region 111-2. In some embodiments, gate dielectric 112 includes one or more insulating materials (e.g., silicon dioxide, silicon oxynitride, hafnium dioxide, alumina oxide, zirconium oxide, or other gate dielectric materials known by one of ordinary skill in the art).

Gate dielectric 112 is disposed between metallization region 140 and semiconductor material 101. Metallization region 140 includes a plurality of sequential layers including a pre-metal or inter-layer dielectric layer M0, a first metal layer M1, a second metal layer M2, and so on until a target number of layers are included in metallization region 140. Each layer included in metallization region 140 includes wires or vias (e.g., to provide routing between circuitry components, form ground lines, bitlines, or the like) isolation by, or otherwise disposed within respective layers of one or more insulating materials (e.g., insulating materials 141, 142, and/or 143). In some embodiments, insulating materials 141, 142, 143, and/or other insulating materials included in metallization region 140 include or otherwise correspond to silicon dioxide, a tetraethylorthosilicate, a high density plasma oxide material, other insulating materials, or combinations thereof. It is appreciated that layer M0 corresponds to an interlayer dielectric layer or pre-metal dielectric layer disposed closest to gate dielectric 112 relative to any other layer included in metallization region 140. In the illustrated embodiment, first transfer gate electrode 109-1, second transfer gate electrode 109-2, reset gate electrode 113, and/or other gate electrodes included in pixel cell 105-1 are formed within M0 while wires 131 are formed within one or more layers (e.g., Layers M0, M1, and M2 as illustrated) included in metallization region 140. For example, wires 131 may traverse a lateral distance within layer M2 and a vertical distance through layers M1 and M0 to couple first floating diffusion region 111-1 and second floating diffusion region 111-2 formed within semiconductor material 101 to source-follower gate electrode 115 formed in layer M0 (not illustrated in FIG. 1C).

FIG. 1D illustrates a partial view of pixel cell array 105 illustrated in FIG. 1A including an example two-by-two arrangement of pixel cells each having a split floating diffusion, in accordance with an embodiment of the disclosure. Pixel cells 105_{1,1}, 105_{1,2}, 105_{2,1}, and 105_{2,2} correspond to instances of pixel cell 105-1 illustrated in FIGS. 1B and 1C with different color filters to form, for example, a full color pixel cell (e.g., pixel cells 105_{1,1} and 105_{2,2} may correspond to green pixel cells, pixel cell 105_{1,2} may correspond to a red pixel cell, and 105_{2,1} may correspond to a blue color pixel cell). Accordingly, pixel cells 105_{1,1}, 105_{1,2}, 105_{2,1}, and 105_{2,2} may have the same or similar components as pixel cell 105-1 illustrated in FIGS. 1B and 1 C, which are not individually numbered for brevity but labeled in terms of functionality for clarity (e.g., PD1, PD2, PD3, PD4 corresponding to first, second, third, and fourth photodiodes, TX1, TX2, TX3, and TX4 corresponding to first, second, third, and fourth transfer gate electrodes, reset gate electrode RST, source-follower gate electrode SF, and row select gate electrode RS).

However, it is noted that components formed in first transistor area 180-1 and second transistor area 180-2 may be aligned based on the layout of pixel cell 105-1 illustrated in FIG. 1B and reproduced, in part, in FIG. 1D. For example, pixel cells 105_{1,1} and 105_{1,2} correspond to adjacent pixel cells formed in the same row (e.g., a first row included in a plurality of rows) and different columns (e.g., a first column and a second column included in a plurality of columns where the first column is adjacent to the second column). In the illustrated embodiment, split floating diffusions FD and reset gate electrodes RST of column-adjacent pixel cells are aligned such that floating diffusion regions of the split floating diffusions are disposed between the reset gate electrodes RST (e.g., floating diffusion regions included in pixel cells 105_{1,1} and 105_{1,2} are disposed between the reset gate electrode of pixel cell 105_{1,1} formed in first transistor area 180-1 and the reset gate electrode RST of pixel cell 105_{1,2} formed in second transistor area 180-2). In another example, pixel cells 105_{1,1} and 105_{2,1} correspond to adjacent pixel cells formed in the column row (e.g., a first column included in a plurality of columns) and different rows (e.g., a first row and a second row included in a plurality of rows where the first row is adjacent to the second row). In the illustrated embodiment, components included in first transistor area 180-1 in row-adjacent pixel cells are aligned (e.g., the reset gate electrode RST, source-follower gate electrode SF, and row select gate electrode RS of pixel cell 105_{1,1} are each aligned with each other as well as the reset gate electrode RST, source-follower gate electrode SF, and row select gate electrode RS of pixel cell 105_{2,1}).

It is appreciated that for various embodiments of the disclosure illustrated in FIG. 1A-1D and elsewhere, additional or fewer components may be included. For example, pixel cell 105-1 illustrated in FIG. 1B-1C may include a different configuration of photodiodes (e.g., one, two, eight, sixteen, or more photodiodes). Similarly, there may be more or fewer transfer transistors depending, for example, on the number of photodiodes included in pixel cell 105-1. Other components known in the art (e.g., nitride spacers, isolation wells, etc.) are omitted for the sake of clarity, but may otherwise be included in embodiments of the disclosure.

FIG. 2 illustrates a plan view of an example layout for a pixel cell 205-1 with a split floating diffusion 211 that is capable of dual conversion gain operation for high dynamic range imagining applications, in accordance with an embodiment of the disclosure. Put in another way, pixel cell 205-1 corresponds to pixel cell 105-1 illustrated in FIG. 1B modified to be capable of adjusting floating diffusion capacitance to enable dual conversion gain readout (e.g., a high conversion gain mode and a low conversion gain mode). For example, a high conversion gain mode may be utilized during low light conditions while a low conversion gain mode may be utilized during normal or bright light conditions. Accordingly, pixel cell 205-1 includes many of the same or like-labeled elements as pixel cell 105-1 of FIG. 1B. It is appreciated that descriptions for elements of pixel cell 105-1 may similarly be applied to like-labeled elements of pixel cell 205-1 illustrated in FIG. 2.

Pixel cell 205-1 includes a plurality of photodiodes 207 including a first photodiode (PD1) 207-1, a second photodiode (PD2) 207-2, a third photodiode (PD3) 207-3, and a fourth photodiode (PD4) 207-4, a plurality of transfer gate electrodes 209 including a first transfer gate electrode (TX1) 209-1 associated with a first transfer transistor, a second transfer gate electrode (TX2) 209-2 associated with a second transfer transistor, a third transfer gate electrode (TX3) 209-3 associated with a third transfer transistor, and a fourth transfer gate electrode (TX4) 209-4 associated with a fourth transfer transistor, split floating diffusion (FD) 211 including first floating diffusion region 211-1 and second floating diffusion region 211-2, a reset gate electrode (RST) 213 associated with a reset transistor, a source-follower gate electrode (SF) 215 associated with a source-follower transistor, a row select gate electrode (RS) 217 associated with a row select transistor, and a plurality of source/drain regions including source/drain regions 222, 224, 226, and 228 associated with the aforementioned reset transistor, source-follower transistor, and/or row select transistor, and one or more interconnects (e.g., one or more wires and vias represented by one or more wires 231); each of which is formed in or on semiconductor material 201. In some embodiments, pixel cell 205-1 further includes an isolation structure 203 formed in semiconductor material 201. Similar to pixel cell 105-1 of FIG. 1B, source-drain regions 222 and 224 may correspond to or otherwise be coupled to respective voltage sources (e.g., to receive an analog voltage such as AVDD), source/drain region 226 corresponds to a shared source/drain region associated with source-follower gate electrode 215 and row select gate electrode 217, and source/drain region 228 corresponds to or is otherwise coupled to a bitline included in a plurality of bitlines (e.g., plurality of bitlines 171 illustrated in FIG. 1A).

A difference between pixel cell 105-1 illustrated in FIG. 1B and pixel cell 205-1 illustrated in FIG. 2 is that pixel cell 205-1 includes a dual floating diffusion gate electrode 219 associated with a dual floating diffusion transistor and a second floating diffusion 230. Specifically, dual floating diffusion gate electrode 219 is disposed between (e.g., adjacent to) first floating diffusion region 211-1 and second floating diffusion region 211-2 while plurality of photodiodes 207 and plurality of transfer gate electrodes 209 each laterally surround split floating diffusion 211. Thus, while the layout for pixel cell 105-1 illustrated in FIG. 1B may be considered a reset-centric configuration, the layout for pixel cell 205-1 is a dual floating diffusion-centric configuration. As illustrated, dual floating diffusion gate electrode 219 is further disposed between reset gate electrode 213 and source-follower gate electrode 215 while source-follower gate electrode 215 is disposed between dual floating diffusion gate electrode 219 and row select gate electrode 217. In the embodiment, a distance (e.g., signal connection, signal routing, separation distance, or lateral spacing distance) between each of first floating diffusion region 211-1 and second floating diffusion region 211-2 to dual floating diffusion gate electrode 219 is less than a distance from first floating diffusion region 211-1 and second floating diffusion region 211-2 to source-follower gate electrode 215 of the source-flower transistor. In some embodiments, components formed within transistor area 280 disposed between a first pair of photodiodes (e.g., first photodiode 207-1 and third photodiode 207-3) and a second pair of photodiodes (e.g., second photodiode 207-2 and fourth photodiode 207-4) are aligned. For example, dual floating diffusion gate electrode 219 is disposed between first photodiode 207-1 and second photodiode 207-2 and further is disposed between third photodiode 207-3 and fourth photodiode 207-4. In another example, any combination of reset gate electrode 213, dual floating diffusion gate electrode 219, source-follower gate electrode 215, and row select gate electrode 217 may be aligned (e.g., centers and/or edges aligned) with one another.

In the illustrated embodiment, second floating diffusion 230 is disposed between reset gate electrode 213 and dual floating diffusion gate electrode 219. In such a way, first floating diffusion region 211-1 extends from within semiconductor material 201 from proximate to a first pair of transfer gate electrodes (e.g., first transfer gate electrode 209-1 and third transfer gate electrode 209-3) continuously towards proximate dual floating diffusion gate electrode 219 to form junction region 214-1, second floating diffusion region 211-2 extends from within semiconductor material 201 from proximate to a second pair of transfer gate electrodes (e.g., second transfer gate electrode 209-2 and fourth transfer gate electrode 209-4) continuously towards proximate dual floating diffusion gate electrode 219 to form junction region 214-2, and second floating diffusion 230 extends within semiconductor material 201 from proximate reset gate electrode 213 to dual floating diffusion gate electrode 219 to form junction region 214-3. Consequently, when an appropriate bias or voltage is applied to dual floating diffusion gate electrode 219 to turn on the associated dual floating diffusion transistor split floating diffusion 211 is coupled to second floating diffusion 230 to increase the effective capacitance associated with pixel cell 205-1 during readout (e.g., corresponding to low conversion gain readout).

It is appreciated that pixel cell 205-1 may be afforded the same benefits and advantages (e.g., simplified metal routing, reduced layers within metallization region, symmetric design for reduced fixed pattern noise) as pixel cell 105-1 with split floating diffusion 211 having reduced capacitance (e.g., due, for example, to reduced or shorted interconnection wiring) relative to floating diffusions in conventional CMOS pixel cell layouts while also enabling dual conversion mode readout to enhance the dynamic range of pixel cell 205-1.

FIG. 3 illustrates a plan view of an example layout for a pixel cell 305-1 with a split floating diffusion 311 that is capable of triple conversion gain operation, in accordance with an embodiment of the disclosure. Put in another way, pixel cell 305-1 corresponds to pixel cell 105-1 illustrated in FIG. 1B and/or pixel cell 205-1 illustrated in FIG. 2 modified to be capable of adjusting floating diffusion capacitance to enable triple conversion gain readout (e.g., a high conversion gain mode with a first effective floating diffusion capacitance, a low conversion gain mode with a second effective floating diffusion capacitance greater than the first effective floating diffusion capacitance, and a lateral overflow integration capacitor gain mode with a third effective floating diffusion capacitance greater than both the first effective floating diffusion capacitance and the second effective floating diffusion capacitance). For example, a high conversion gain mode may be utilized during low light conditions, a low conversion gain mode may be utilized during normal light conditions, and a lateral overflow integration capacitor gain mode may be utilized during bright light conditions to increase the dynamic range of pixel cell 305-1. Accordingly, pixel cell 305-1 includes many of the same or like-labeled elements as pixel cell 105-1 of FIG. 1B and pixel cell 205-1 of FIG. 2. It is appreciated that descriptions for elements of pixel cell 105-1 and pixel cell 205-1 may similarly be applied to like-labeled elements of pixel cell 305-1 illustrated in FIG. 3.

Pixel cell 305-1 includes a plurality of photodiodes 307 including a first photodiode (PD1) 307-1, a second photodiode (PD2) 307-2, a third photodiode (PD3) 307-3, and a fourth photodiode (PD4) 307-4, a plurality of transfer gate electrodes 309 including a first transfer gate electrode (TX1) 309-1 associated with a first transfer transistor, a second transfer gate electrode (TX2) 309-2 associated with a second transfer transistor, a third transfer gate electrode (TX3) 309-3 associated with a third transfer transistor, and a fourth transfer gate electrode (TX4) 309-4 associated with a fourth transfer transistor, split floating diffusion (FD) 311 including first floating diffusion region 311-1 and second floating diffusion region 311-2, a second floating diffusion (FD2) 330, a reset gate electrode (RST) 313 associated with a reset transistor, a source-follower gate electrode (SF) 315 associated with a source-follower transistor, a row select gate electrode (RS) 317 associated with a row select transistor, a dual floating diffusion gate electrode (DFD) 319 associated with a dual floating diffusion transistor, a plurality of source/drain regions including source/drain regions 322, 324, 326, and 328 associated with the aforementioned reset transistor, source-follower transistor, and/or row select transistor, and one or more interconnects (e.g., one or more wires and vias represented by one or more wires 331); each of which is formed in or on semiconductor material 301. In some embodiments, pixel cell 305-1 further includes an isolation structure 303 formed in semiconductor material 301. Similar to pixel cell 105-1 of FIG. 1B and pixel cell 205-1 of FIG. 2, source-drain regions 322 and 324 may correspond to or otherwise be coupled to respective voltage sources (e.g., to receive an analog voltage such as AVDD), source/drain region 326 corresponds to a shared source/drain region associated with source-follower gate electrode 315 and row select gate electrode 317, and source/drain region 328 corresponds to or is otherwise coupled to a bitline included in a plurality of bitlines (e.g., plurality of bitlines 171 illustrated in FIG. 1A).

A difference between pixel cell 305-1 relative to pixel cells 105-1 and 205-1 respectively illustrated in FIG. 1B and FIG. 2 is pixel cell 305-1 further includes a lateral overflow gate electrode (LFG) 321 associated with a lateral overflow transistor, a second reset gate electrode (RST2) 323 associated with a second reset transistor for lateral overflow integration capacitor reset operation, and source/drain regions 332 and 334 disposed in semiconductor material 301. Specifically, source/drain regions 332 and 334 are coupled to opposite electrodes or plates of a lateral overflow integration capacitor. In the same or other embodiments, source/drain region 334 may also be coupled to a voltage source (e.g., such that one of the electrodes included in the lateral overflow integration capacitor may be biased to a pre-determined voltage). As illustrated, reset gate electrode 313, source-follower gate electrode 315, row select gate electrode 317, dual floating diffusion gate electrode 319, lateral overflow gate electrode 321, and second reset gate electrode 323 are each disposed within transistor area 380 between a first pair of photodiodes (e.g., first photodiode 307-1 and third photodiode 307-3) and a second pair of photodiodes (e.g., second photodiode 307-2 and fourth photodiode 307-4). In the illustrated embodiment, lateral overflow gate electrode 321 is disposed between reset gate electrode 313 and dual floating diffusion gate electrode 319, reset gate electrode 313 is disposed between lateral overflow gate electrode 321 and second reset gate electrode 323, and dual floating diffusion gate electrode 319 is disposed between lateral overflow gate electrode 321 and source-follower gate electrode 315. In some embodiments, components formed within transistor area 380 are aligned. For example, any combination of reset gate electrode 313, source-follower gate electrode 315, row select gate electrode 317, dual floating diffusion gate electrode 319, lateral overflow gate electrode 321, and second reset gate electrode 323 may be aligned (e.g., centers and/or edges aligned) with one another. In one embodiment, reset gate electrode 313, source-follower gate electrode 315, row select gate electrode 317, dual floating diffusion gate electrode 319, lateral overflow gate electrode 321, and second reset gate electrode 323 extend or are otherwise arranged or positioned along direction 390. In the same or another embodiment, first floating diffusion region 311-1, second floating diffusion region 311-2, and dual floating diffusion gate electrode 319 extend or are otherwise arranged or positioned along direction 392. In some embodiments direction 390 is perpendicular to direction 392.

In some embodiments, when an appropriate bias or voltage is applied to lateral overflow gate electrode 321 and dual floating diffusion gate electrode 319 to turn on the respective lateral overflow transistor and dual floating diffusion transistor then split floating diffusion 311 is coupled to second floating diffusion 330 and the lateral overflow integration capacitor coupled to source/drain region 332 to increase the effective capacitance associated with pixel cell 305-1 during readout (e.g., corresponding to a lateral overflow integration capacitor or LOFIC conversion gain readout). In such a manner, depending on the states of the dual floating diffusion transistor (e.g., based on a bias applied to dual floating diffusion gate electrode 319) and the lateral overflow transistor (e.g., based on a bias applied to later overflow gate electrode 321), the effective capacitance associated with the floating diffusion for pixel cell 305-1 may be varied to readout image charge during the a high conversion gain mode, a low conversion gain mode, or a lateral overflow integration capacitor conversion gain mode.

It is appreciated that pixel cell 305-1 may be afforded the same benefits and advantages (e.g., simplified metal routing, reduced layers within metallization region, symmetric design for reduced fixed pattern noise) as pixel cells 105-1 and 205-1 with split floating diffusion 311 having reduced capacitance (e.g., due, for example, to reduced or shorted interconnection wiring) relative to floating diffusions in conventional CMOS pixel cell layouts while also enabling triple conversion mode readout.

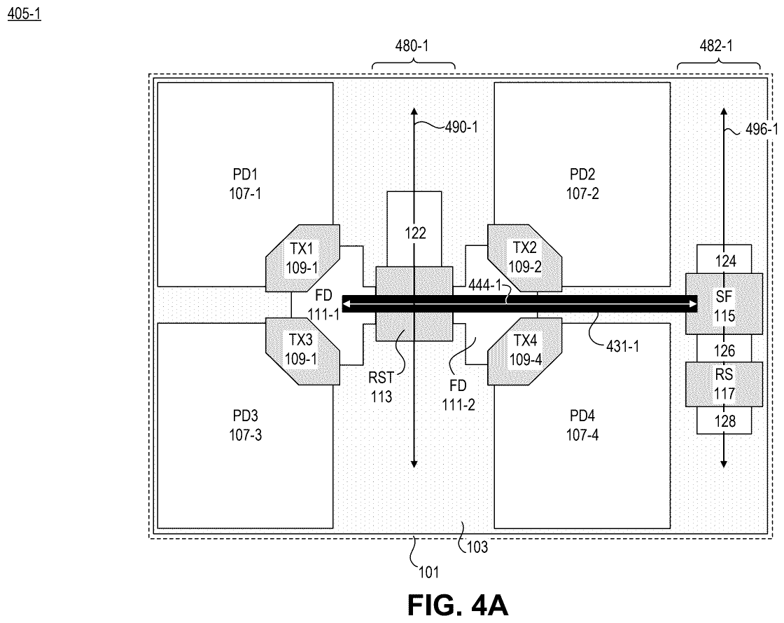

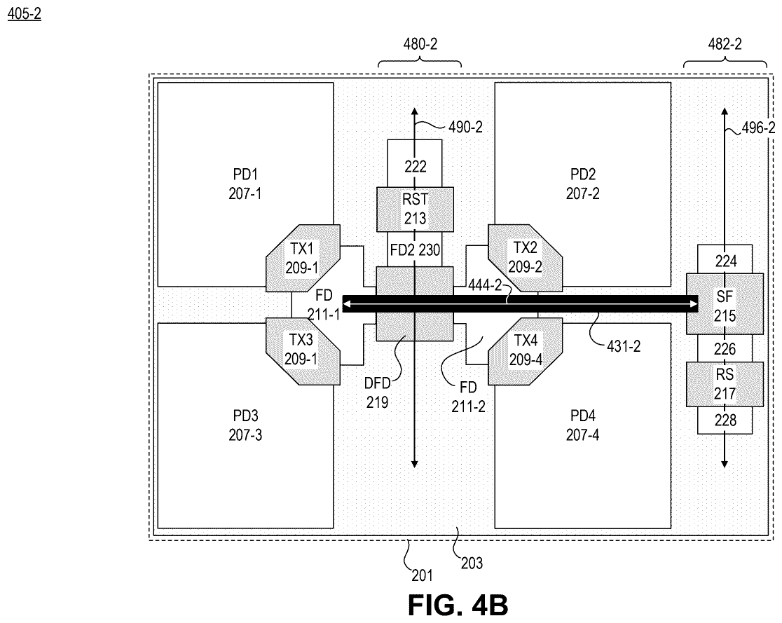

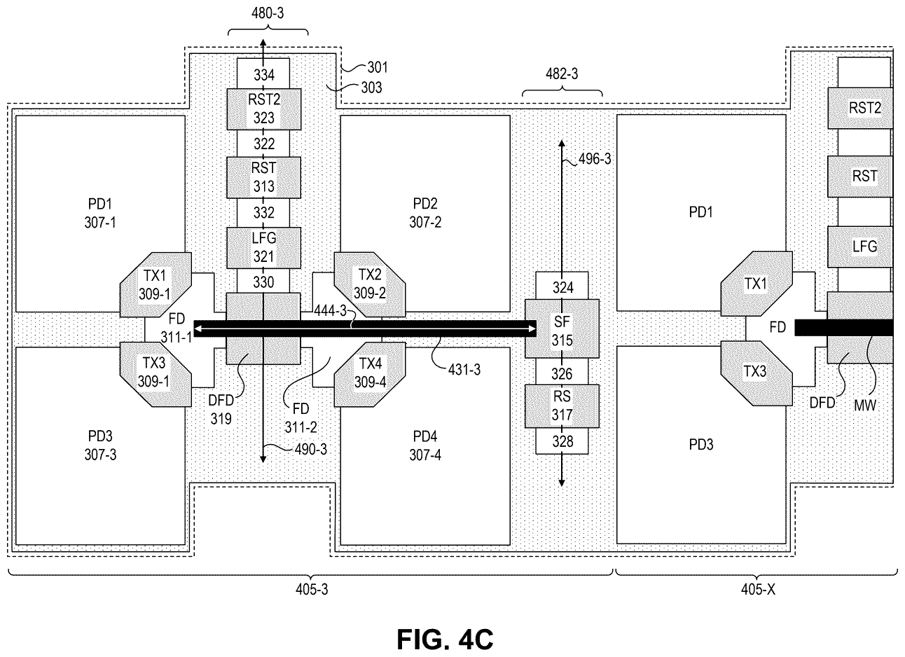

FIGS. 4A, 4B, and 4C illustrate example layouts for pixel cells 405-1, 405-2, and 405-3 respectively correspond to pixel cells 105-1, 205-1, and 305-1 from FIGS. 1B, 2, and 3 configured to a parallel source-follower gate electrode arrangement, in accordance with embodiments of the disclosure. Accordingly, pixel cells 405-1, 405-2, and 405-3 include many of the same or like-labeled elements as pixel cells 105-1, 205-1, and 305-1 illustrated in FIGS. 1B, 2, and 3. It is appreciated that descriptions for elements of pixel cells 105-1, 205-1, and 305-1 may similarly be applied to like-labeled elements of pixel cells 405-1, 405-2, and 405-3 illustrated in FIG. 4A-4C.

FIG. 4A illustrates pixel cell 405-1 corresponding to pixel cell 105-1 illustrated in FIG. 1B with a parallel source-follower gate electrode arrangement, in accordance with an embodiment of the disclosure. In the illustrated embodiment, active pixel transistor circuitry is split between a first transistor area 480-1 and a second transistor area 482-1 (e.g., defined by isolation structure 103). As illustrated, split floating diffusion 111 including first floating diffusion region 111-1 and second floating diffusion region 111-2, reset gate electrode 113, and source/drain region 122 are disposed within or overlap with first transistor area 480-1 when viewed from a plan view. First transistor area 480-1 is disposed between a first pair of photodiodes (e.g., first photodiode 107-1 and third photodiode 107-3) and a second pair of photodiodes (e.g., second photodiode 107-2 and fourth photodiode 107-4). In the same embodiment, source-follower gate electrode 115, row select gate electrode 117, and source/drain regions 124, 126, and 128 overlap with or are positioned within second transistor area 482-1 such that the second pair of photodiodes is disposed between circuity included in the first transistor area 480 and circuitry included in second transistor area 482-1. Put in another way, the second pair of photodiodes is disposed between first transistor area 480-1 and second transistor area 482-1.

In some embodiments, reset gate electrode 113 positioned within first transistor area 480-1 is disposed parallel to or otherwise aligned with source-follower gate electrode 115 positioned within second transistor area 482-1. In some embodiments, centers or edges of reset gate electrode 113 and source-follower gate electrode 115 may overlap along a same direction (e.g., components are arranged or positioned along direction 444-1). In some embodiments, direction 444-1 overlaps with first floating diffusion region 111-1, second floating diffusion region 111-2, reset gate electrode 113, and source-follower gate electrode 115. In the same or other embodiments, a first wire 431-1 included in one or more wires that couple first floating diffusion region 111-1 and second floating diffusion region 111-2 to source-follower gate electrode 115 extends along or parallel to direction 444-1 (e.g., continuously from first floating diffusion region 111-1 to source-follower gate electrode 115). In some embodiments, second floating diffusion region 111-2 is disposed between first floating diffusion region 111-1 and source-follower gate electrode 115 when viewed from the plan view such that first wire 431-1 overlaps first floating diffusion region 111-1, second floating diffusion region 111-2, reset gate electrode 113, and source-follower gate electrode 115.

In the same or other embodiments, circuitry components disposed within or overlapping with first transistor area 480-1 (e.g., reset gate electrode 113 and source/drain region 122) extend or are otherwise arranged or positioned along direction 490-1 and circuitry components disposed within or overlapping with second transistor area 482-1 (e.g., source-follower gate electrode 115, row select gate electrode 117, and source/drain regions 124, 126, and 128) extend or are otherwise arranged or positioned along direction 496-1. In some embodiments, direction 490-1 and 496-1 are parallel to one another. In the same or another embodiment, direction 490-1 and/or direction 496-1 are perpendicular to direction 444-1 (e.g., first wire 431-1 extends along a direction perpendicular to directions 490-1 and 496-1 that circuitry components overlapping with or disposed within first transistor area 480-1 and second transistor area 482-1 extend along). In some embodiments, a length of first wire 431-1 corresponds to approximately (e.g., within 10% or less) of a pixel cell pitch (e.g., distance between centers of adjacent pixel cells).

It is appreciated the parallel source-follower gate electrode arrangement of FIG. 4A provides simplified routing and additional space consideration (e.g., active pixel circuitry components may be disposed between the first and second pair of photodiodes but also between adjacent pixel cells).

FIG. 4B illustrates pixel cell 405-2 corresponding to pixel cell 205-1 illustrated in FIG. 2 with a parallel source-follower gate electrode arrangement, in accordance with an embodiment of the disclosure. In the illustrated embodiment, active pixel transistor circuitry is split between first transistor area 480-2 and second transistor area 482-2 (e.g., defined by isolation structure 203). As illustrated, split floating diffusion 211, reset gate electrode 213, dual floating diffusion gate electrode 219, source/drain region 222, and second floating diffusion 230 are disposed within or overlap with first transistor area 480-2 when viewed from a plan view. First transistor area 480-2 is disposed between a first pair of photodiodes (e.g., first photodiode 207-1 and third photodiode 207-3) and a second pair of photodiodes (e.g., second photodiode 207-2 and fourth photodiode 207-4). In the same embodiment, source-follower gate electrode 215, row select gate electrode 217, and source/drain regions 224, 226, and 228 overlap with or are positioned within second transistor area 482-2 such that the second pair of photodiodes is disposed between circuity included in the first transistor area 480-2 and circuitry included in second transistor area 482-2. Put in another way, the second pair of photodiodes is disposed between first transistor area 480-2 and second transistor area 482-2.

In some embodiments, dual floating diffusion gate electrode 219 positioned within first transistor area 480-2 is disposed parallel to or otherwise aligned with source-follower gate electrode 215 positioned within second transistor area 482-2. In some embodiments, centers or edges of dual floating diffusion gate electrode 219 and source-follower gate electrode 215 may overlap along a same direction (e.g., components are arranged or positioned along direction 444-2). In some embodiments, direction 444-2 overlaps with first floating diffusion region 211-1, second floating diffusion region 211-2, dual floating diffusion gate electrode 219, and source-follower gate electrode 215. In the same or other embodiments, a first wire 431-2 included in one or more wires that couple first floating diffusion region 211-1 and second floating diffusion region 211-2 to source-follower gate electrode 215 extends along or parallel to direction 444-2 (e.g., continuously from first floating diffusion region 211-1 to source-follower gate electrode 215). In some embodiments, second floating diffusion region 211-2 is disposed between first floating diffusion region 211-1 and source-follower gate electrode 215 when viewed from the plan view such that first wire 431-2 overlaps first floating diffusion region 211-1, second floating diffusion region 211-2, dual floating diffusion gate electrode 219, and source-follower gate electrode 215.

In the same or other embodiments, circuitry components disposed within or overlapping with first transistor area 480-2 (e.g., reset gate electrode 213, second floating diffusion 230, and source/drain region 222) extend or are otherwise arranged or positioned along direction 490-2 and circuitry components disposed within or overlapping with second transistor area 482-2 (e.g., source-follower gate electrode 215, row select gate electrode 217, and source/drain regions 224, 226, and 228) extend or are otherwise arranged or positioned along direction 496-2. In some embodiments, direction 490-2 and 496-2 are parallel to one another. In the same or another embodiment, direction 490-2 and/or direction 496-2 are perpendicular to direction 444-2 (e.g., first wire 431-2 extends along a direction perpendicular to directions 490-2 and 496-2 that circuitry components overlapping with or disposed within first transistor area 480-2 and second transistor area 482-2 extend along). In some embodiments, a length of first wire 431-2 corresponds to approximately (e.g., within 10% or less) of a pixel cell pitch (e.g., distance between centers of adjacent pixel cells).

It is appreciated the parallel source-follower gate electrode arrangement of FIG. 4B provides simplified routing and additional space consideration (e.g., active pixel circuitry components may be disposed between the first and second pair of photodiodes but also between adjacent pixel cells).

FIG. 4C illustrates pixel cell 405-3 corresponding to pixel cell 305-1 illustrated in FIG. 3 with a parallel source-follower gate electrode arrangement, in accordance with an embodiment of the disclosure. FIG. 4C further illustrates a partial view of pixel cell 405-X (e.g., corresponding to an instance of pixel cell 405-3 with a different color filter) immediately adjacent to pixel cell 405-3. Pixel cell 405-X includes the same or similar elements as pixel cell 405-3, which have not been labeled for clarity, but illustrates photodiodes PD1, PD3, transfer gate electrodes TX1 and TX3, split floating diffusion FD, dual floating diffusion gate electrode DFD, lateral overflow gate electrode LFG, reset gate electrode RST, second reset gate electrode RST2, and metal wire MW.

In the illustrated embodiment, active pixel transistor circuitry for pixel cell 405-3 is split between first transistor area 480-3 and second transistor area 482-3 (e.g., defined by isolation structure 303). As illustrated, split floating diffusion 311 including first floating diffusion region 311-1 and second floating diffusion region 311-2, reset gate electrode 313, dual floating diffusion gate electrode 319, lateral overflow gate electrode 321, second reset gate electrode 323, second floating diffusion 330, and source/drain regions 322, 332, and 334 are disposed within or overlap with first transistor area 480-3 when viewed from a plan view. First transistor area 480-3 is disposed between a first pair of photodiodes (e.g., first photodiode 307-1 and third photodiode 307-3) and a second pair of photodiodes (e.g., second photodiode 307-2 and fourth photodiode 307-4). In the same embodiment, source-follower gate electrode 315, row select gate electrode 317, and source/drain regions 324, 326, and 328 overlap with or are positioned within second transistor area 482-3 such that the second pair of photodiodes is disposed between circuity included in the first transistor area 480-3 and circuitry included in second transistor area 482-3. Put in another way, the second pair of photodiodes is disposed between first transistor area 480-3 and second transistor area 482-3. Additionally, second transistor area 482-3 is disposed between pixel cell 405-X (e.g., a pair of photodiodes including photodiodes PD1 and PD3 of pixel cell 405-X) and the second pair of photodiodes of pixel cell 405-3.

In some embodiments, dual floating diffusion gate electrode 319 positioned within first transistor area 480-3 is disposed parallel to or otherwise aligned with source-follower gate electrode 315 positioned within second transistor area 482-3. In some embodiments, centers or edges of dual floating diffusion gate electrode 319 and source-follower gate electrode 315 may overlap along a same direction (e.g., components are arranged or positioned along direction 444-3). In some embodiments, direction 444-3 overlaps with first floating diffusion region 311-1, second floating diffusion region 311-2, dual floating diffusion gate electrode 319, and source-follower gate electrode 315. In the same or other embodiments, a first wire 431-3 included in one or more wires that couple first floating diffusion region 311-1 and second floating diffusion region 311-2 to source-follower gate electrode 315 extends along or parallel to direction 444-3 (e.g., continuously from first floating diffusion region 311-1 to source-follower gate electrode 315). In some embodiments, second floating diffusion region 311-2 is disposed between first floating diffusion region 311-1 and source-follower gate electrode 315 when viewed from the plan view such that first wire 431-3 overlaps first floating diffusion region 311-1, second floating diffusion region 311-2, dual floating diffusion gate electrode 319, and source-follower gate electrode 315.

In the same or other embodiments, circuitry components disposed within or overlapping with first transistor area 480-3 (e.g., reset gate electrode 313, dual floating diffusion gate electrode 319, second floating diffusion 330, lateral overflow gate electrode 321, second reset gate electrode 323, and source/drain regions 322, 332, and 334) extend or are otherwise arranged or positioned along direction 490-3 and circuitry components disposed within or overlapping with second transistor area 482-3 (e.g., source-follower gate electrode 315, row select gate electrode 317, and source/drain regions 324, 326, and 328) extend or are otherwise arranged or positioned along direction 496-3. In some embodiments, directions 490-3 and 496-3 are parallel to one another. In the same or another embodiment, direction 490-3 and/or direction 496 are perpendicular to direction 444-3 (e.g., first wire 431-3 extends along a direction perpendicular to directions 490-3 and 496-3 that circuitry components overlapping with or disposed within first transistor area 480-3 and second transistor area 482-3 extend along). In some embodiments, a length of first wire 431-3 corresponds to approximately (e.g., within 10% or less) of a pixel cell pitch (e.g., distance between centers of adjacent pixel cells such as distance between the center of pixel cell 405-3 and pixel cell 405-X). It is further appreciated that the illustrated view provided by FIG. 4C shows source-follower gate electrode 315 of pixel cell 405-3 disposed between dual floating diffusion gate electrode 319 of pixel cell 405-3 and the dual floating diffusion gate electrode DFD of pixel cell 405-X. In some embodiments, centers or edges of source-follower gate electrode 315 of pixel cell 405-3, dual floating diffusion gate electrode 319 of pixel cell 405-3, and dual floating diffusion gate electrode DFD of pixel cell 405-X are aligned.

It is appreciated the parallel source-follower gate electrode arrangement of FIG. 4C provides simplified routing and additional space consideration (e.g., active pixel circuitry components may be disposed between the first and second pair of photodiodes but also between adjacent pixel cells).

It is appreciated that embodiments of the disclosure illustrated in FIG. 1A-4C may be fabricated using conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is appreciated that the described techniques are merely demonstrative and not exhaustive and that other techniques may be utilized to fabricate one or more components of various embodiments of the disclosure.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A pixel cell for an image sensor, comprising:
a plurality of photodiodes, including a first photodiode and a second photodiode, formed in a semiconductor material configured to generate image charge in response to incident light;
a split floating diffusion formed in the semiconductor material including a first floating diffusion region and a second floating diffusion region;
a plurality of transfer gate electrodes, including a first transfer gate electrode and a second transfer gate electrode, adapted to transfer the image charge to the split floating diffusion, wherein the first transfer gate electrode is disposed between the first photodiode and the first floating diffusion region and the second transfer gate electrode is disposed between the second photodiode and the second floating diffusion region; and
a gate electrode of a transistor coupled to and disposed between the first floating diffusion region and the second floating diffusion region, wherein the first floating diffusion region and the second floating diffusion region form respective junction regions of the transistor.

2. The pixel cell of claim 1, wherein the plurality of photodiodes further includes a third photodiode and a fourth photodiode, wherein the first and the third photodiodes are vertically aligned, and the second and fourth photodiodes are vertically aligned, wherein the plurality of transfer gate electrodes includes a third transfer gate electrode and a fourth transfer gate electrode, wherein the first floating diffusion region extends continuously within the semiconductor material from proximate to the gate electrode to proximate both the first transfer gate electrode and the third transfer gate electrode when viewed from a plan view, and wherein the second floating diffusion region extends continuously within the semiconductor material from proximate to the gate electrode to proximate both the second transfer gate electrode and the fourth transfer gate electrode when viewed from the plan view.

3. The pixel cell of claim 2, wherein the transistor and the gate electrode respectively correspond to a reset transistor and a reset gate electrode or a dual floating diffusion transistor and a dual floating diffusion gate electrode, and wherein the gate electrode is laterally surrounded by the plurality of transfer gate electrodes and the plurality of photodiodes.

4. The pixel cell of claim 1, further comprising a source-follower gate electrode of a source-follower transistor coupled to the first floating diffusion region and the second floating diffusion region through one or more wires formed within a metallization region.

5. The pixel cell of claim 4, wherein the source-follower gate electrode is disposed between the first photodiode and the second photodiode, wherein a first lateral distance from the first floating diffusion region or the second floating diffusion region to the gate electrode of the transistor is less than a second lateral distance from the first floating diffusion region or the second floating diffusion to the source-follower gate electrode.

6. The pixel cell of claim 4, further comprising a second floating diffusion formed within the semiconductor material proximate to the gate electrode to form a corresponding junction region of the transistor, wherein the transistor corresponds to a dual floating diffusion transistor and the gate electrode corresponds to a dual floating diffusion gate electrode.

7. The pixel cell of claim 6, further comprising a reset transistor including a reset gate electrode, wherein the second floating diffusion is disposed between the reset gate electrode and the dual floating diffusion gate electrode, wherein the dual floating diffusion gate electrode is disposed between the reset gate electrode and the source-follower gate electrode, and wherein the dual floating diffusion gate electrode is disposed between the first photodiode and the second photodiode.

8. The pixel cell of claim 7, further comprising a lateral overflow transistor and a second reset transistor formed between the first photodiode and the second photodiode, wherein the lateral overflow transistor includes a lateral overflow gate electrode disposed between the reset gate electrode and the dual floating diffusion gate electrode, wherein the second reset transistor includes a second reset gate electrode, and wherein the reset gate electrode is disposed between the lateral overflow gate electrode and the second reset gate electrode.

9. The pixel cell of claim 4, further comprising a row select gate electrode of a row select transistor coupled to the source-follower transistor, wherein the gate electrode corresponds to a reset gate electrode such that the transistor corresponds to a reset transistor or the gate electrode corresponds to a dual floating diffusion gate electrode such that the transistor corresponds to a dual floating diffusion transistor, and wherein the gate electrode, the source-follower gate electrode, and the row select gate electrode are aligned along a direction extending between the first photodiode and the second photodiode.

10. The pixel cell of claim 4, further comprising an isolation structure formed within the semiconductor material to define a first transistor area and a second transistor area, wherein the first transistor area is disposed between the first photodiode and the second photodiode, wherein the second photodiode is disposed between the first transistor area and the second transistor area, wherein the isolation structure includes at least one of a trench isolation structure or an implantation isolation structure, and wherein the gate electrode overlaps with the first transistor area when viewed from a plan view.

11. The pixel cell of claim 10, wherein the source-follower gate electrode overlaps with the second transistor area, wherein the one or more wires includes a first wire extending from the first floating diffusion region to the source-follower gate electrode, and wherein the second floating diffusion region is disposed between the first floating diffusion region and the source-follower gate electrode when viewed from the plan view such that the first wire overlaps the first floating diffusion region, the second floating diffusion region, and the source-follower gate electrode.

12. The pixel cell of claim 11, wherein a length of the first wire corresponds to approximately a pixel cell pitch.

13. The pixel cell of claim 11, wherein the transistor and the gate electrode respectively correspond to a reset transistor and a reset gate electrode or a dual floating diffusion transistor and a dual floating diffusion gate electrode.

14. The pixel cell of claim 11, further comprising a reset transistor formed within the first transistor area and a row select transistor formed within the second transistor area, wherein a reset gate electrode included in the reset transistor and the gate electrode included in the transistor are arranged along a first direction, wherein the source-follower gate electrode and a row select gate electrode included in the row select transistor are arranged along a second direction parallel to the first direction, and wherein the first wire extends along a third direction perpendicular to both the first direction and the second direction.

15. The pixel cell of claim 4, wherein the source-follower gate electrode is aligned with the gate electrode of the transistor.

16. An image sensor, comprising:
a plurality of pixel cells arranged in rows and columns to form a pixel cell array, wherein individual pixel cells included in the plurality of pixel cells each include:
a plurality of photodiodes, including a first pair of photodiodes and a second pair of photodiodes, formed in a semiconductor material;
a split floating diffusion formed in the semiconductor material including a first floating diffusion region and a second floating diffusion region;
a plurality of transfer gate electrodes disposed between the first pair of photodiodes and the first floating diffusion region and a second pair of transfer gate electrodes disposed between the second pair of photodiodes and the first floating diffusion region; and
a gate electrode of a transistor disposed between the first floating diffusion region and the second floating diffusion region, wherein the first floating diffusion region extends within the semiconductor material from proximate to the first pair of transfer gate electrodes to proximate to the gate electrode, and wherein the second floating diffusion region extends within the semiconductor material from proximate to the second pair of transfer gate electrodes to proximate to the gate electrode.

17. The image sensor of claim 16, wherein the transistor and the gate electrode respectively correspond to a reset transistor and a reset gate electrode or a dual floating diffusion transistor and a dual floating diffusion gate electrode.

18. The image sensor of claim 16, wherein the transistor is coupled to the first floating diffusion region and the second floating diffusion region without any metal wire connection.

19. The image sensor of claim 16, wherein each of the individual pixel cells further include a source-follower gate electrode of a source-follower transistor coupled to the first floating diffusion region and the second floating diffusion region through one or more wires formed within a metallization region.

20. The image sensor of claim 19, wherein the plurality of pixel cells includes a first pixel cell and a second pixel cell adjacent to the first pixel cell, wherein the source-follower gate electrode of the first pixel cell is disposed between the gate electrode of the first pixel cell and the gate electrode of the second pixel cell, wherein a first wire included in the one or more of the first pixel cell overlaps with the first floating diffusion region, the second floating diffusion region, the gate electrode, and the source-follower gate electrode of the first pixel cell when viewed from a plan view, and wherein a length of the first wire is approximately a pitch between centers of the first pixel cell and the second pixel cell.
